(19) United States
(12) Patent Application Publication
(10) Pub. No.: US 2019/0148201 A1
(43) Pub. Date: May 16, 2019

(54) WAFER POSITIONING AND LOADING SYSTEM

(71) Applicant: Beijing Chuangyu Technology Co., Ltd., Beijing (CN)

(72) Inventors: Bingbing Shen, Beijing (CN); Min Wei, Beijing (CN)

(21) Appl. No.: 16/120,136

(22) Filed: Aug. 31, 2018

(30) Foreign Application Priority Data
Nov. 16, 2017 (CN) 201711138110.4

(51) Int. Cl. H01L 21/68; B25J 15/06; H01L 21/683; G08B 21/18

(52) U.S. Cl. CPC H01L 21/681; G08B 21/187; H01L 21/6838; B25J 15/0616

(57) ABSTRACT

The present disclosure relates to a wafer positioning and loading system, which includes a picking mechanism, a visual positioning system, a feeding mechanism, and an alignment platform system including a plurality of sub-alignment platforms. The picking mechanism includes an X-direction picking manipulator and a YZ-direction conveying unit, a plurality of first vacuum chucks arranged at intervals for sucking up wafers is disposed on the X-direction picking manipulator, the plurality of first vacuum chucks corresponds one-to-one to the plurality of sub-alignment platforms; the visual positioning system is arranged above the alignment platform system for obtaining the position of the wafers; each the sub-alignment platform adjusts the positions of the wafers according to the positions of the wafers obtained, so that they are coincident with the preset reference position; the feeding mechanism is used for conveying the plurality of wafers adjusted on the plurality of sub-alignment platforms to the destination.

### CLAIM OF PRIORITY

This application claims priority to Chinese Patent Application No. 201711138110.4, filed on Nov. 16, 2017, the entire contents of which are incorporated herein in their entirety.

### TECHNICAL FIELD

The present disclosure relates to the field of semiconductor production technology, and in particular to a wafer positioning and loading system.

### BACKGROUND

In the current production process of solar cells and semiconductor wafers, the entire loading process of wafers is mostly completed by a manipulator. The manipulator first takes out a wafer from the wafer cassette and places it on the alignment platform for photographing and positioning. After adjusting the center position of the wafer, the manipulator sucks up the wafer again and puts it into wet process equipment or a designated container. The entire process has long cycle time and low production efficiency and cannot meet the requirements of mass production due to relying on one manipulator to complete grabbing, placing, transferring and other actions of the wafer; however, the cost is relatively higher if plurality of manipulators and alignment platforms is used.

### SUMMARY

### (I) Technical Problem to be Solved

It is an object of the present disclosure to provide a wafer positioning and loading system, which is intended to solve one of the technical problems existing in the prior art or related art

### (II) Technical Solutions

In order to solve the technical problems above, the present disclosure provides a wafer positioning and loading system, including: a picking mechanism, a visual positioning system, a feeding mechanism, and an alignment platform system including a plurality of sub-alignment platforms.

The picking mechanism includes an X-direction picking manipulator and a YZ-direction conveying unit; a plurality of first vacuum chucks arranged at intervals for sucking up wafers is disposed on the X-direction picking manipulator; the plurality of first vacuum chucks corresponds one-to-one to the plurality of sub-alignment platforms; and the YZ-direction conveying unit is connected with the X-direction picking manipulator so as to simultaneously convey the wafers sucked by the plurality of the first vacuum chucks to the respective corresponding sub-alignment platforms.

The visual positioning system is arranged above the alignment platform system for obtaining the positions of the wafers on each of the sub-alignment platforms.

Each of the sub-alignment platforms adjusts the wafers according to the position of each of the wafers obtained by the visual positioning system, such that the position of which is coincident with the preset reference position.

The feeding mechanism is used for conveying the plurality of wafers adjusted on the plurality of sub-alignment platforms to the destination.

The YZ-direction conveying unit includes a guide rail; the guide rail includes a Y-direction segment and Z-direction segments respectively connected to both ends of the Y-direction segment; both of the Z-direction segments are positioned below the Y-direction segment, and one end of the X-direction picking manipulator is slidably connected with the guide rail.

The YZ-direction conveying unit further includes a driving device for driving the X-direction picking manipulator to slide in the guide rail.

The YZ-direction conveying unit includes a guide rail; the guide rail including a Y-direction guide rail and a Z-direction guide rail; wherein the Z-direction guide rail is slidably connected with the Y-direction guide rail, and one end of the X-direction picking manipulator is slidably connected with the Z-direction guide rail.

The YZ-direction conveying unit further includes a first driving device for driving the X-direction picking manipulator to slide in the Z-direction guide rail and a second driving device for driving the Z-direction guide rail to slide in the Y-direction guide rail.

The plurality of sub-alignment platforms is arranged in a line.

The wafer positioning and loading system further includes an X-direction slide rail arranged above the alignment platform system; and the visual positioning system is slidably connected with the X-direction slide rail.

The plurality of sub-alignment platforms is arranged in an M×N array, where 2.

The wafer positioning and loading system further includes an X-direction slide rail arranged above the alignment platform system; the visual positioning system is slidably connected with the X-direction slide rail; a Y-direction slide rail is disposed at a lower end of the X-direction slide rail; and the X-direction slide rail is slidably connected with the Y-direction slide rail.

The sub-alignment platforms are UVW alignment platforms.

The feeding mechanism includes an X-direction feeding manipulator and a Y-direction feeding guide rail disposed above the alignment platform system; a plurality of second vacuum chucks are is disposed on the X-direction feeding manipulator; the plurality of second vacuum chucks corresponds one-to-one to the plurality of sub-alignment platforms; the X-direction feeding manipulator is slidably connected with the Y-direction guide rail; and the alignment platform system can move up and down in the Z direction.

The feeding mechanism further includes an X-direction feeding manipulator and a feeding guide rail disposed above the alignment platform system; the feeding guide rail includes a Y-direction segment and Z-direction segments connected with the Y-direction segment; the Z-direction segments are located below the Y-direction segment and corresponds to the alignment platform system; the Z-direction segments divide the Y-direction segment into a first portion at the front and a second portion at the rear; and one end of the X-direction picking manipulator is slidably connected to the feeding guide rail.

The wafer positioning and loading system further includes an alarm device with a detection unit and an alarm unit; the detection unit is used for detecting whether the first vacuum chucks fail to suck up the same wafer consecutively A times, and wherein, A>2; when it is detected that the consecutive suctions fail, an instruction is sent to the alarm unit, and the alarm unit issues an alarm.

The first vacuum chucks are made of rubber or plastic; or, the first vacuum chucks are made of metal, and the surfaces of the vacuum chucks are coated with a flexible material layer.

### (III) Advantageous Effects

The wafer positioning and loading system provided by the present disclosure can operate on multiple wafers at the same time, reducing the time occupied by repetitive actions of the equipment, thus improving working efficiency and decreasing the cost.

Further, instead of using a plurality of cameras to capture positions of the wafers one to one, the wafer positioning and loading system provided by the present disclosure obtains the position of each wafer by photographing positions of multiple wafers one by one using a movable visual positioning system, thereby further decreasing the cost.

### BRIEF DESCRIPTION OF THE DRAWINGS

FIG. 1 is a schematic structural view of a preferred embodiment of a wafer positioning and loading system according to the present disclosure.

FIG. 2 is a process flow chart of a wafer positioning and loading system according to the present disclosure.

FIG. 3 is a schematic structural view of another preferred embodiment of a wafer positioning and loading system according to the present disclosure.

In the drawings, 1: wafer; 2: picking mechanism; 3: visual positioning system; 4: alignment platform system; 5: feeding mechanism; 6: Y-direction slide rail.

### DETAILED DESCRIPTION

Detailed description of the present disclosure is further described in detail below in combination with the accompanying drawings and embodiments. The following embodiments are used to explain the present disclosure, but are not used to limit the scope of the present disclosure.

In the description of the present disclosure, it is to be construed that the orientation or position relationship indicated by terms “center”, “longitudinal”, “lateral”, “length”, “width”, “thickness”, “up”, “down”, “front”, “rear”, “left”, “right”, “vertical”, “horizontal”, “top”, “bottom”, “inside”, “outside”, “clockwise”, “counterclockwise”, “axial”, “radial”, “circumferential” and so forth is based on the orientation or position relationship illustrated by the accompanying drawings, they are only for the convenience of describing the present disclosure and simplifying the description, rather than indicating or implying that the device or element referred to must have a particular orientation, be constructed and operated in a particular orientation, and thus, cannot be interpreted as a limitation of the present disclosure.

Furthermore, terms “first” and “second” are used for descriptive purposes only and are not to be construed as indicating or implying relative importance or implicitly demonstrating the number of technical features indicated. Thus, features defined as “first” and “second” may explicitly or implicitly include at least one such feature. In the description of the present disclosure, the meaning of “plurality” is at least two, such as two, three, etc., unless expressly and specifically defined otherwise.

In the present disclosure, unless otherwise specifically defined or limited, the terms “installed”, “interconnected”, “connected”, “fixed” and the like should be understood in a broad sense, for example, it can be a fixed connection, it can be a detachable connection, or it can be integrated; it can be a mechanical connection, an electrical connection, or a communication with each other; it can be directly connected or indirectly connected through an intermediary, and it can be the internal communication of two elements or the interaction of two elements, unless otherwise expressly defined. Those of ordinary skill in the art can understand the specific meanings of the above terms in the present disclosure according to specific circumstances.

### Embodiment 1

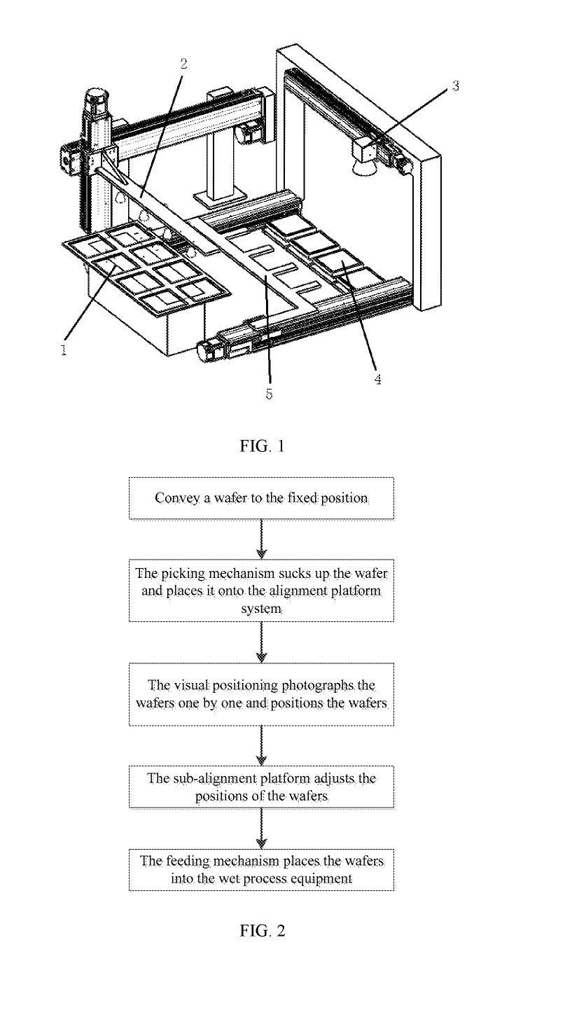

FIG. 1 illustrates a preferred embodiment of a wafer positioning and loading system according to the present disclosure. As shown, the wafer positioning and loading system includes a picking mechanism 2, a visual positioning system 3, a feeding mechanism 5, and an alignment platform system 4 including a plurality of sub-alignment platforms. The picking mechanism 2 includes an X-direction picking manipulator and a YZ-direction conveying unit, plurality of first vacuum chucks arranged at intervals for sucking up wafers are disposed on the X-direction picking manipulator, so as to simultaneously grab multiple wafers 1 by the X-direction picking manipulator. Specifically, the first vacuum chucks are connected to vacuum equipment through an exhaust pipe, and the first vacuum chucks is set at the bottom end of the X-direction picking manipulator with the sucking surface facing downward. The plurality of first vacuum chucks corresponds one-to-one to the plurality of sub-alignment platforms. The YZ-direction conveying unit is connected with the X-direction picking manipulator for simultaneously conveying the wafers 1 sucked up by the plurality of first vacuum chucks to respective corresponding sub-alignment platforms. The visual positioning system 3 is arranged above the alignment platform system 4 for obtaining the position (preferably the center position) of the wafers 1 on each the sub-alignment platform; each the sub-alignment platform adjusts the positions of the wafers 1 according to the positions of the wafers 1 obtained by the visual positioning system 3, so that they are coincident with the preset reference position. The feeding mechanism 5 is used for conveying the plurality of wafers 1 adjusted on the plurality of sub-alignment platforms to the destination, for example, in the wet process equipment or designated container.

The wafer positioning and loading system provided by the present disclosure is capable of simultaneously picking of multiple wafers 1 by employing the plurality of first vacuum chucks arranged at intervals on the X-direction picking manipulator, simultaneously conveying multiple wafers 1 to respective corresponding sub-alignment platforms by the YZ-direction conveying unit, and then obtaining the position of each of the wafers 1 placed on the plurality of sub-alignment platforms by the visual positioning system 3; adjusting the position of each of the wafers 1 according to the position of each wafer 1 obtained by the visual positioning system 3 by each sub-alignment platform, respectively; and finally, conveying the multiple wafers 1 adjusted on the plurality of sub-alignment platforms to the destination by the feeding mechanism 5. The wafer positioning and loading system provided by the present disclosure can operate on multiple wafers at the same time, reducing the time occupied by repetitive actions of the equipment, thus improving working efficiency and decreasing the cost.

Specifically, in this embodiment, the YZ-direction conveying unit includes a guide rail; the guide rail includes a Y-direction guide rail and a Z-direction guide rail; wherein the Z-direction guide rail is slidably connected with the Y-direction guide rail, and one end of the X-direction picking manipulator is slidably connected with the Z-direction guide rail. Preferably, the YZ-direction conveying unit further includes a first driving device for driving the X-direction picking manipulator to slide in the Z-direction guide rail and a second driving device for driving the Z-direction guide rail to slide in the Y-direction guide rail. When the YZ-direction conveying unit is working, the X-direction picking manipulator first slides up along the Z-direction guide rail to the desired position and stops, and then the Z-direction guide rail slides horizontally along the Y-direction guide rail, such that the X-direction picking manipulator connected to the Z-direction guide rail slides horizontally along the Y-direction guide rail to the desired position (at which position, the plurality of first vacuum chucks of the X-direction picking manipulator corresponds one-to-one to the plurality of sub-alignment platforms in the alignment platform system 4) and stops. Subsequently, the X-direction picking manipulator slides down along the Z-direction guide rail to place the wafers 1 on the alignment platform system 4. At this time, the plurality of first vacuum chucks on the X-direction picking manipulator releases the sucked wafers 1 onto the respective corresponding sub-alignment platforms, and then backtracks, so as to grab the next batch of wafers 1.

It is to be noted that, it should be understood by those skilled in the art that in other embodiments of the present disclosure, other structures may be used for the YZ-direction conveying unit, as long as the X-direction picking manipulator can be moved to the position corresponding to the alignment platform system 4 (that is, the plurality of first vacuum chucks of the X-direction picking manipulator can correspond one-to-one to the plurality of sub-alignment platforms in the alignment platform system 4). For example, the YZ-direction conveying unit includes a guide rail; the guide rail includes a Y-direction segment and two Z-direction segments respectively connected to both ends of the Y-direction segment; both of the Z-direction segments are positioned below the Y-direction segment (that is, the guide rail is inverted “U” shaped); and one end of the X-direction picking manipulator is slidably connected with the guide rail. Preferably, the YZ-direction conveying unit also includes a driving device for driving the X-direction picking manipulator to slide in the guide rail, so as to drive the X-direction picking manipulator to slide in the guide rail driven by the driving device. Specifically, the X-direction picking manipulator first moves upward along one of the Z-direction segments of the guide rail, then moves horizontally along the Y-direction segment, and finally moves downward along the other Z-direction segment, so as to convey the wafers 1 sucked by the first vacuum chucks to the alignment platform system 4.

It is to be noted that, although it is illustrated in this embodiment that the number of sub-alignment platforms in the alignment platform system 4 is four and these four sub-alignment platforms are arranged in a line. It should be understood by those skilled in the art that in other embodiments of the present embodiment, the number of sub-alignment platforms in the alignment platform system 4 can also be other values, for example, 2, 5, or 8 etc.

In this embodiment, the wafer positioning and loading system also includes an X-direction slide rail and a visual positioning system 3 arranged above the alignment platform system 4, wherein, the visual positioning system 3 is slidably connected with the X-direction slide rail, so as to obtain the positions of the wafers 1 on the plurality of sub-alignment platforms successively by moving the visual positioning system 3. During operation, after obtaining the position of one of the wafers, the visual positioning system 3 moves to the position of the next wafer 1, so as to detect the next wafer 1. When the visual positioning system 3 photographs one of the wafers 1, the sub-alignment platform corresponding to the wafer 1 can adjust the wafer 1 according to the position of the wafer 1 obtained by the visual positioning system 3, thereby further improving the working efficiency and decreasing the manufacturing cost.

It is to be noted that, it should be understood by those skilled in the art that in some embodiments of the present disclosure, a plurality of fixed visual positioning system 3 can also be used, and each visual positioning system 3 corresponds one-to-one to one of the sub-alignment platforms so as to photograph the wafers one-to-one.

Preferably, the sub-alignment platforms employ the UVW sub-alignment platforms. Further, the zero point of each sub-alignment platform is to obtain the reference position by wet process equipment or a designated container or other destination. When the center position of the wafer 1 coincides with the set value of the sub-alignment platform, it is equivalent to also coincide with the center position of the wet process equipment or designated container, thereby guaranteeing the placement accuracy of the wafer 1 in the wet process equipment or designated container.

The feeding mechanism 5 includes an X-direction feeding manipulator and a Y-direction guide disposed above the alignment platform system 4, a plurality of second vacuum chucks is disposed on the X-direction feeding manipulator, the X-direction feeding manipulator is slidably connected with the Y-direction guide rail, and the alignment platform system 4 can move up and down along the Z direction. Specifically, the alignment platform system 4 is mounted on a floor controlled by a jack cylinder, such that the alignment platform system 4 can move up and down along the Z axis. After the visual positioning system 3 obtains the center position of the wafer 1, the sub-alignment platform adjusts according to a preset reference position, such that the center position of the wafer 1 coincides with the set position. When the X-direction feeding manipulator moves to the top of the alignment platform system 4, the plurality of second vacuum chucks corresponds one-to-one to the plurality of sub-alignment platforms in the alignment platform system 4, so as to simultaneously grab the wafers 1 on the plurality of sub-alignment platforms and convey the wafers 1 to the destination.

It is to be noted that, it should be understood by those skilled in the art that in other embodiments of the present disclosure, the alignment platform system 4 remains unchanged in the Z direction, whereas the feeding mechanism 5 is depressed such that the second vacuum chucks suck up the wafers 1 on the alignment platform system 4. Specifically, the feeding mechanism 5 also includes an X-direction feeding manipulator and a feeding guide rail disposed above the alignment platform system 4, wherein, the feeding guide rail includes a Y-direction segment and Z-direction segments connected with the Y-direction segment, the Z-direction segment is located below the Y-direction segment, the Z-direction segments divides the Y-direction segment into a first portion at the front and a second portion at the rear, and one end of the X-direction feeding manipulator is slidably connected with the guide rail. After each of the sub-alignment platforms adjusts the wafers 1 according to the position of each of the wafers 1 obtained by the visual positioning system 3 and when the X-direction feeding manipulator of the feeding mechanism 5 moves horizontally to the Z-direction segment along the first portion of the Y-direction segment of the feeding guide rail, the positions of the plurality of second vacuum chucks correspond to the positions of the wafers 1 on the plurality of sub-alignment platforms, and the X-direction feeding manipulator moves downward along the Z-direction segment, sucks up the wafers 1 on the alignment platform system 4, and then moves upward along the Z-direction segment, conveys the wafers 1 into the wet process equipment or designated container, and returns along the Y-direction segment.

Further, the wafer 1 positioning and loading system also includes an alarm device, the alarm device includes a detection unit and an alarm unit, wherein, the detection unit is used for detecting whether the first vacuum chucks fail to suck up the same wafer consecutively A times, and preferably, A>2, when it is detected that the consecutive suctions fail, an instruction is sent to the alarm unit, and the alarm unit issues an alarm. That is, it is determined by the degree of vacuum when the first vacuum chucks of the picking mechanism 2 sucks the wafer 1, and if a vacuum cannot be formed, repeat the attempt A times, then prove that the wafer 1 is broken and issue an alarm.

Furthermore, in order to prevent damage to the wafer 1, the vacuum chucks are preferably made of rubber or plastic; in other embodiments of the present disclosure, the vacuum chucks can also be made of metal. When the vacuum chucks are made of metal, the surface of the vacuum chucks is preferably coated with a layer of a flexible material, for example, a rubber layer or a plastic layer.

The workflow of the wafer positioning and loading system is as follows: as illustrated in FIG. 2, the wafer 1 placed in the container is placed on the platform at the designated position by the front-end equipment, positioned and fixed; after the wafer 1 is put in place, the picking mechanism 2 moves to the top of the wafer 1, moves down to the wafer 1, the first vacuum chuck sucks four wafers 1 simultaneously, the end lifts and moves to the top of the alignment platform system 4, and finally places the wafer 1 onto the alignment platform system 4. When the wafer is placed onto the alignment platform system 4, the visual positioning system 3 starts to photograph the wafers 1 one by one, and determines the positions of the wafers 1. After the visual positioning system 3 obtains the positions of the wafers, the alignment platform system 4 adjusts according to the preset reference position, such that the positions of the wafers 1 coincide with the set position. After adjusting the positions of the wafers 1, the feeding mechanism 5 moves to the alignment platform system 4, and the jack cylinder lifts the alignment platform system 4 to a certain height. The second vacuum chuck at the end of the feeding mechanism 5 simultaneously sucks up four wafers, then advances and puts the wafers into the wet process equipment. A loading process is completed and the cycle is repeated.

### Embodiment 2

The present embodiment is substantially the same as embodiment 1, and for simplicity of description, the same technical features as those of embodiment 1 will not be described in the description of this embodiment, while only the difference between the present embodiment and the embodiment 1 will be described:

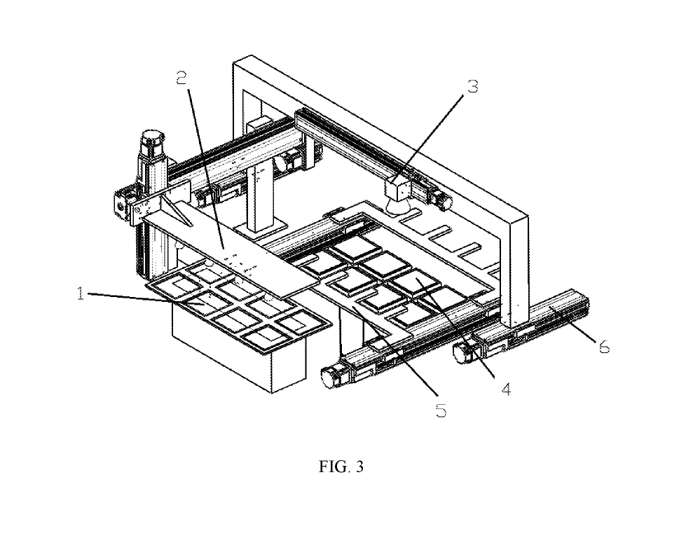

As illustrated in FIG. 3, in this embodiment, the plurality of sub-alignment platforms are arranged in a 4×2 matrix. In this case, the X-direction picking manipulator is plate-shaped, and the plurality of first vacuum chucks provided thereon is also arranged in a 4×2 matrix. It is to be noted that, although it is illustrated in this embodiment that the sub-alignment platforms in the alignment platform system 4 are arranged in a 4×2 matrix, it should be understood by those skilled in the art that in other embodiments of the present embodiment, the sub-alignment platforms in the alignment platform system 4 can also be arranged in a M×N matrix, wherein, M≥2, N≥2, such as 3×3, or 5×3, etc.

The wafer positioning and loading system also includes an X-direction slide rail and a visual positioning system 3 arranged above the alignment platform system 4, wherein, the visual positioning system 3 is slidably connected with the X-direction slide rail, a Y-direction slide rail 6 is also disposed at the end of the X-direction slide rail, the X-direction slide rail is slidably connected with the Y-direction slide rail 6, such that the visual positioning system 3 successively obtains the positions of multiple wafers 1 on the sub-alignment platform in the same X-direction by moving the visual positioning system 3 on the X-direction slide rail, and then the X-direction slide rail moves along the Y-direction slide rail 6, such that the visual positioning system 3 successively obtains the positions of multiple wafers 1 on the sub-alignment platform in another X-direction. When the visual positioning system 3 photographs one of the wafers 1, the sub-alignment platform corresponding to the wafer 1 can adjust the wafer 1 according to the position of the wafer 1 obtained by the visual positioning system 3, thereby further improving the working efficiency and decreasing the manufacturing cost.

In other embodiments of the present disclosure, the plurality of sub-alignment platforms of the alignment platform system 4 is arranged in an M×N matrix. In this case, The wafer positioning and loading system also includes an X-direction slide rail arranged above the alignment platform system 4 and N Y-direction sub-slide rails disposed on the X-direction slide rail, wherein, the N Y-direction sub-slide rails correspond one-to-one to the N columns of the plurality of the sub-alignment platforms, and the number of the visual positioning system 3 is N, each visual positioning system 3 is slidably connected with a corresponding Y-direction sub-slide rail, such that one visual positioning system 3 photographs the wafers 1 on a corresponding column of the sub-alignment platform in the M×N matrix arrangement, and N visual positioning systems 3 can operate simultaneously to further improve working efficiency.

The above-mentioned description is only a preferred embodiment of the present disclosure and is not intended to limit the present disclosure. Any modifications, equivalent replacements, improvements, etc. within the spirit and principle of the present disclosure should be included in the protection scope of the present disclosure.

1. A wafer positioning and loading system, comprising:
a picking mechanism, a visual positioning system, a feeding mechanism, and an alignment platform system including a plurality of sub-alignment platforms, wherein,
the picking mechanism comprises an X-direction picking manipulator and a YZ-direction conveying unit, a plurality of first vacuum chucks arranged at intervals for sucking up wafers is disposed on the X-direction picking manipulator, the plurality of first vacuum chucks corresponds one-to-one to the plurality of sub-alignment platforms, the YZ-direction conveying unit is connected with the X-direction picking manipulator so as to simultaneously convey the wafers sucked by the plurality of the first vacuum chucks to the respective corresponding sub-alignment platforms;
the visual positioning system is arranged above the alignment platform system for obtaining the positions of the wafers on each of the sub-alignment platforms;
each of the sub-alignment platforms adjusts the wafers according to the position of each of the wafers obtained by the visual positioning system, such that the position of each of the wafers is coincident with the preset reference position;
the feeding mechanism is used for conveying the plurality of wafers adjusted on the plurality of sub-alignment platforms to the destination.

2. The wafer positioning and loading system of claim 1, wherein the YZ-direction conveying unit comprises a guide rail; the guide rail comprises a Y-direction segment and Z-direction segments respectively connected to both ends of the Y-direction segment; both of the Z-direction segments are positioned below the Y-direction segment, and one end of the X-direction picking manipulator is slidably connected with the guide rail.

3. The wafer positioning and loading system of claim 2, wherein the YZ-direction conveying unit further comprises a driving device for driving the X-direction picking manipulator to slide in the guide rail.

4. The wafer positioning and loading system of claim 1, wherein the YZ-direction conveying unit comprises a guide rail; the guide rail comprises a Y-direction guide rail and a Z-direction guide rail; the Z-direction guide rail is slidably connected with the Y-direction guide rail, and one end of the X-direction picking manipulator is slidably connected with the Z-direction guide rail.

5. The wafer positioning and loading system of claim 4, wherein the YZ-direction conveying unit further comprises a first driving device for driving the X-direction picking manipulator to slide in the Z-direction guide rail and a second driving device for driving the Z-direction guide rail to slide in the Y-direction guide rail.

6. The wafer positioning and loading system of claim 1, wherein the plurality of sub-alignment platforms is arranged in a line.

7. The wafer positioning and loading system of claim 6, wherein it further comprises an X-direction slide rail arranged above the alignment platform system, and the visual positioning system is slidably connected with the X-direction slide rail.

8. The wafer positioning and loading system of claim 1, wherein the plurality of sub-alignment platforms is arranged in an M×N array, where M≥2, N≥2.

9. The wafer positioning and loading system of claim 8, wherein it further comprises an X-direction slide rail arranged above the alignment platform system; the visual positioning system is slidably connected with the X-direction slide rail; a Y-direction slide rail is disposed at a lower end of the X-direction slide rail, and the X-direction slide rail is slidably connected with the Y-direction slide rail.

10. The wafer positioning and loading system of claim 1, wherein the sub-alignment platform is a UVW alignment platform.

11. The wafer positioning and loading system of claim 1, wherein the feeding mechanism comprises an X-direction feeding manipulator and a Y-direction feeding guide rail disposed above the alignment platform system; a plurality of second vacuum chucks is disposed on the X-direction feeding manipulator; the plurality of second vacuum chucks corresponds one-to-one to the plurality of sub-alignment platforms; the X-direction feeding manipulator is slidably connected with the Y-direction guide rail, and the alignment platform system can move up and down in the Z direction.

12. The wafer positioning and loading system of claim 1, wherein the feeding mechanism further comprises an X-direction feeding manipulator and a feeding guide rail disposed above the alignment platform system; the feeding guide rail comprises a Y-direction segment and Z-direction segments connected with the Y-direction segment; the Z-direction segments are located below the Y-direction segment and correspond to the alignment platform system; the Z-direction segments divide the Y-direction segment into a first portion at the front and a second portion at the rear, and one end of the X-direction picking manipulator is slidably connected to the feeding guide rail.

13. The wafer positioning and loading system of claim 1, wherein it further comprises an alarm device with a detection unit and an alarm unit; the detection unit is used for detecting whether the first vacuum chucks fail to suck up the same wafer consecutively A times, and wherein, A>2; when it is detected that the consecutive suctions fail, an instruction is sent to the alarm unit, and the alarm unit issues an alarm.

14. The wafer positioning and loading system of claim 1, wherein the first vacuum chucks are made of rubber or plastic; or, the first vacuum chucks are made of metal, and the surfaces of the vacuum chucks are coated with a flexible material layer.
